(19) United States
(12) Patent Application Publication
(10) Pub. No.: US 2011/0217573 A1
(43) Pub. Date: Sep. 8, 2011

(54) Sensor for Selectively Detecting Liquids in Apparatuses for Storing and Generating Energy

(75) Inventors: Peter Kritzer, Forst (DE); Marcel Schreiner, Mannheim (DE)

(73) Assignee: CARL FREUDENBERG KG, Weinheim (DE)

(21) Appl. No.: 12/942,760

(22) Filed: Nov. 9, 2010

(30) Foreign Application Priority Data
Mar. 2, 2010 (EP) 10002114.6

(51) Int. Cl. H01M 10/48; G01R 27/26

(52) U.S. Cl. 429/61; 324/663; 429/90

(57) ABSTRACT

A sensor for detecting liquids in apparatuses for storing energy, an apparatus for storing energy, a monitoring system for monitoring apparatuses for storing energy, and a method for monitoring apparatuses for storing energy are provided.

### CROSS-REFERENCE TO RELATED APPLICATIONS

This application claims the benefit and priority of European Application No. 10 002 114.6, filed Mar. 2, 2010. The entire disclosure of the above application is incorporated herein by reference.

### FIELD

The present disclosure relates to a sensor for detecting liquids in apparatuses for storing energy, an apparatus for storing energy, a monitoring system for monitoring apparatuses for storing energy, and a method for monitoring apparatuses for storing energy.

### BACKGROUND

This section provides background information related to the present disclosure which is not necessarily prior art.

As developments in the field of automobile and motor vehicle technology advance, apparatuses for storing energy, such as batteries, accumulator batteries and super capacitors for electric vehicles, are becoming increasingly important. Apparatuses of these types for storing energy are arranged in housings, in which hermetically shielded energy storage cells are located. The housings serve to mechanically fix the cells in position and to protect them from damage. The intact housings themselves contain no liquids during normal operation, and instead encompass a dry inner chamber.

Electrochemical storage systems of this type are also being increasingly used as back-up energy stores for other mobile applications (e.g., in rail vehicles, aircraft) and for stationary applications.

Batteries are also being used especially for industrial transport applications (robots, industrial trucks, forklifts).

Liquids can be used in battery housings, depending upon the system. These liquids have various sources and various chemical/physical properties; the consequences of their presence also vary widely. The different liquids which can be used in battery housings include, particularly: condensation water (generally demineralized water); waste water (generally water with ionic components, comparable with tap water); medium from the cooling circuit (generally water containing antifreeze additives such as glycol); and electrolyte from the cells (depending upon the type of cells (a) aqueous solutions, containing high ion concentrations, for example, from H₂SO₄ or KOH additives, (b) polar organic solvents containing high concentrations of so-called conducting salts, such as LiPF₆).

One particular challenge is that the reaction varies widely, depending upon the source of the liquid. For example, if condensation water is detected in a battery housing, said water should be removed during the next routine interval; however, the presence of electrolyte outside of the cells is an extremely critical situation; in such cases the battery should not continue to be used under any circumstances.

The housings customarily contain an open area that cannot be filled with cells, a so-called dead volume. In batteries, this space makes up about 5% of the volume of the housing. The dead volume can also make up significantly more than 5%, for example if geometrically disadvantageous round cells are used for energy storage.

Apparatuses for storing energy, such as fuel cells or batteries for motor vehicles and the like, are frequently operated under changing temperature conditions, for example in the change between summer and winter or day and night, which elicits temperature fluctuations inside the housing. In electrically operated motor vehicles, such pressure fluctuations can also occur during uphill driving. For instance, following a period of uphill driving, the interior of the battery housing will have adjusted to a low pressure level. If the vehicle is then moved downhill, surrounding air at a higher pressure will flow into the interior of the battery housing. Because the housing is hermetically sealed, slight overpressures or negative pressures can then occur. This can negatively affect the seal of the energy storage cells located in the battery, thereby affecting the overall lifespan of the apparatus. Moreover, significant pressure fluctuations also negatively affect other components, such as electrical power and monitoring contacts of the energy storage cells and seals of housing feedthroughs for cables; said components may also become leaky.

To reduce pressure fluctuations of this type, the dead volume of batteries of the prior art is filled with silicone insulating compound (Lamm et al., “Lithium-lonen Batterie. Erster Serieneinsatz im S400 Hybrid” [Lithium-Ion Battery. First Series Use in the S400 Hybrid]; 2009, ATZ 111, 490 f.). The disadvantage of this process is that it significantly increases the bulk of the battery. In addition, the process of casting polymer compounds is costly and complicated, not least due to the necessary cross-linking of the silicones. Further, the replacement of individual cells as a part of maintenance and repair is made significantly more difficult.

However, if the dead volume is not filled with solid or liquid media, temperature fluctuations can cause an exchange of air with the surrounding environment. At low temperatures, the relative negative pressure can cause air to enter the housing. This allows both moisture and dust to also enter the housing. The moisture can condense inside the battery, thereby increasing the likelihood of short circuits, corrosion, etc. In a battery having a dead volume of 10 L, with daily operation over a period of 3 years, which is a customary maintenance interval, approximately 50 g condensation water can collect.

In addition, sprayed water, for example, from rain, water puddles, etc., or cleaning water, for example, from high-pressure washers, can reach the interior of the battery housing, since batteries are often located near the floor of a vehicle. This effect can be intensified if the battery housing or its seal has been damaged and has tears or other untight areas.

When stored energy is drawn from the cells, heat is produced, making it necessary to cool the cells. This is customarily achieved through contact cooling with water-based cooling media, for example, in the form of a water/glycol mixture. If there is damage to the cooling system, cooling fluid can enter the battery housing. Cooling medium can also reach the housing interior by permeating elastomeric sealing materials. With typical lifespans of up to 15 years for such battery systems, liquid quantities of >100 g can also collect inside the housing in this manner.

Finally, if there is damage to the cells, electrolyte solution can enter the housing that encompasses the cells. Conductive liquids can be used as electrolytes in apparatuses for storing electrical energy. The electrolytes can be aqueous solutions with dissolved salts, bases or acids. Particularly in lithium accumulator batteries, polar organic solvents, such as diethyl carbonate, are used, wherein said solvents are mixed with salts, such as lithium hexafluorophosphate, for example, in order to increase their conductivity. Super capacitors generally contain polar organic solvents such as acetonitrile.

Sensors for batteries are disclosed in DE 10 2008 013 407 A1 and DE 10 2007 063 280 A1. Said sensors are used to detect the status of a battery. In these cases, the electrical status parameter of a battery, for example, a terminal voltage, is measured and the measured value is transmitted to an evaluation unit.

Sensor systems which can be used to detect leakage are available commercially. Optical fill level sensors, capacitive fill level sensors and metal-clad level sensors with a PTC base are available, for example. However, sensors of this type permit only a non-selective detection of liquids; in other words, they do not differentiate between different types of liquids.

The known sensor systems are non-selective. They do not differentiate between different liquids. Only the signal that a liquid has penetrated into the battery housing is transmitted to the receiver. The disadvantage of the non-selective signal is that it can lead to false conclusions. For instance, an interruption in operation, such as the immediate stoppage of a vehicle, would be unnecessary if instead of electrolyte solution, only condensation water has penetrated into the housing. On the other hand, continued operation of the apparatus would be dangerous if electrolyte has actually entered the housing. However, if the user, for example, of a motor vehicle were to receive a signal that he could continue operation, severe damage could occur, for example, the battery could catch fire.

### SUMMARY

This section provides a general summary of the disclosure, and is not a comprehensive disclosure of its full scope or all of its features.

The object of the invention is to provide a sensor for energy storage systems which will overcome the above-described problems. The object of the present invention is to provide sensors which qualitatively, quantitatively, selectively and reliably detect different liquids that may enter the housing of an apparatus for storing energy. A further object is to provide apparatuses for storing energy, a monitoring system for monitoring apparatuses for storing energy, and methods and applications which utilize such sensors. The sensor should make it possible to control an apparatus for storing energy on the basis of the detected liquid and its quantity. The sensor should therefore also serve to prevent damage and thereby to extend lifespan. In particular, the sensor should be able to differentiate selectively between the penetration of water and that of electrolyte.

Surprisingly, the object is attained with sensors, apparatuses, monitoring systems, methods and applications according to the patent claims.

The subject matter of the present disclosure is a sensor (1) for selectively detecting liquids in apparatuses for storing energy, wherein said sensor (1) comprises at least one porous absorption layer (3) for absorbing liquids.

The sensor (1) preferably selectively detects whether it is in contact with water or with an electrolyte, and/or is not in contact with any liquid. In this case, “selective” means that the sensor is able to differentiate whether it is in contact with water or with an electrolyte solution, for example. With such sensors it is particularly important that they selectively detect the presence of electrolyte. In particular, the sensor preferably selectively differentiates between electrolytes and water. Preferably, even if the sensor has already absorbed water, it is able to accurately detect the additional presence of relatively small quantities of electrolyte. The sensor also preferably detects the quantity of liquid with which it is in contact.

In this context, the term “water” refers to aqueous media which have a low ion concentration and are not suitable for use as electrolytes in apparatuses for storing energy. Such media include especially tap water, distilled water (condensation water), rainwater, cooling water (such as water/glycol mixtures) or water containing cleaning agents. At 27° C., their electrical conductivity is preferably less than 2000 mS/m or less than 500 mS/m.

The selective detection of different liquids makes it possible, on the basis of the respectively detected liquids, to isolate the apparatus from loads, if applicable, and to provide maintenance signals which will notify the driver of a vehicle, for example, that a corresponding fault has occurred, and, if applicable, will provide the driver with options for clearing the fault.

For example, if demineralized water, which is generally formed from condensation water, is detected, a maintenance signal is generated, indicating that condensation water has been detected in the apparatus, and that the apparatus should be replaced and/or the condensation water should be removed from the housing. The condensation water is generally caused by the penetration of moist air into the housing of the apparatus, and usually has an electrical conductivity of less than 1 mS/m under normal conditions.

Tap water usually has an electrical conductivity of about 1 mS/m to 500 mS/m. Tap water can enter the apparatus by water entering from the outside, for example, due to leaks in housing seals of the apparatus. If tap water is detected, assuming the correspondingly detected quantity is not too great, signals similar to those for the detection of condensation water are generated.

If a cooling medium is detected, usually a mixture of an organic substance with water, for example, a water/glycol mixture, this indicates that there is a leak in a cooling circuit of the apparatus. In this case, the accurate and uniform control of the temperature of the individual energy storage and/or generator cells can no longer be guaranteed. A signal is then generated, indicating that the apparatus should be replaced as soon as possible, or the leak should be repaired and the housing dried.

In a preferred embodiment, the sensor is sensitive enough that it can differentiate between different types of water, for example, between condensation water and tap water, or between condensation water, tap water and cooling medium.

Apparatuses according to the invention for storing energy include, in particular, batteries, fuel cells, accumulator batteries and capacitors.

In double-layer capacitors or super-capacitors (“super-caps”), cells containing electrolyte are arranged in a housing. Said cells contain highly polar organic liquids, such as acetonitrile, as the electrolyte. With double-layer capacitors of this type, a loss of electrolyte will place the capacitor in a critical status. The organic electrolytes are inflammable and may ignite on current-carrying components.

Such apparatuses for storing energy contain an electrolyte. According to the invention, an electrolyte is understood as a conductive solution. The conductivity of said solution is high enough that it can be used technically for energy storage. The solvent can be water or an organic solvent. The aqueous solution preferably contains a solvent and a salt, an acid, or a base dissolved therein. Its conductivity is generally above 1 S/m, particularly above 5 S/m or above 10 S/m. The electrolytes can contain customary salts, for example, those of lithium or other alkali metals.

In cell systems, differentiation is generally made between systems with aqueous electrolytes (e.g., lead/acid batteries, nickel/cadmium batteries or nickel/metal hydride batteries) and those with organic electrolytes (e.g., lithium ion batteries or lithium polymer batteries). In lithium batteries, due to the high cell voltage, aqueous electrolytes cannot be used; they would be electrolyzed. Therefore, in such cells, electrochemically stable organic solvents such as organic carbonates are used. To increase ionic conductivity, inert conducting salts such as LiPF₆, for example, are added to these solvents.

If the sensor detects electrolyte in the housing of the apparatus, in other words, outside of the individual cell, this indicates a leak of one or more of the individual cells. The apparatus can then no longer be used to generate and/or store energy, as otherwise, the electrolyte could ignite, for example, on current-carrying parts of a vehicle. Therefore, if such an error occurs, a vehicle equipped with the apparatus should not continue to be moved under any circumstances. Moreover, a cell which loses electrolyte should not be recharged under any circumstances, as this could result in a fire or to an explosion of the cell.

Particularly advantageous is a sensor which, after it has already absorbed water (cooling medium, condensation water or waste water), is able to rapidly and accurately detect the additional presence of electrolyte. Ideally, said sensor is able to detect electrolyte quantities that are very small as compared with the quantities of aqueous media. In other words, the signals for aqueous media and electrolyte should be very different from one another.

The sensor according to the invention is used in apparatuses for storing energy. Such apparatuses ordinarily contain a liquid electrolyte. The electrolyte is present in at least one container. The containers are arranged in a housing, which ordinarily is not filled with or in contact with electrolyte.

The sensor is used in apparatuses for storing energy. The energy is particularly electrochemical energy. The apparatus can release the energy in the form of current. Said apparatus therefore also serves to generate and convert energy.

Advantageously, the sensor is embodied as a capacitive and/or optical sensor.

In one preferred embodiment, the sensor is a capacitive sensor. Said sensor detects a change in the capacitance of an individual capacitor. The advantage of a capacitive sensor is that it can be produced at low cost. It is also robust with respect to contamination with particulates such as dust, etc., and also with respect to shocks and vibrations. Moreover, it can be used in a temperature range of approx. −30° C. to +60° C., which is particularly relevant for a battery of a motor vehicle, and itself has a low temperature dependency. A capacitive sensor is highly sensitive to various liquids and permits quantitative statements with respect to the quantity of the detected liquid. In addition, capacitive sensors permit differentiation between liquids, which could not be, or could be only imprecisely, differentiated from one another using optical sensors. For instance, using a capacitive sensor, even very low concentrations can be detected, for example, a very low concentration of electrolyte in water. When a capacitive sensor is used, electrolytes can be clearly differentiated from other aqueous media. The relative capacitance of the sensor which is in contact with electrolyte is significantly higher than that of the sensor which is in contact with water, with the difference amounting to a factor of at least 2, at least 5, or at least 10.

The sensor can also be an optical sensor, including a UV or infrared sensor. Such an embodiment can make sense, for example, if the electrolyte solution is colored or color marked, or will be colored by a color reaction with a dye or indicator located in the housing. This dye can be located on a substrate, for example, which absorbs the liquid thereby causing a color change.

The sensor is preferably not a switching sensor, which differentiates between only two states, such as a capacitive proximity switch or an optical limit value switch. The sensor preferably operates reversibly, i.e., it can re-release absorbed liquid, thereby returning to its original state, if applicable, following a re-activation step such as rinsing and/or drying. In contrast, mechanical sensors, which are based upon swelling, generally cannot be used reversibly, and cannot be used selectively for different liquids. The sensor is preferably configured in such a way that when it absorbs water, the positioning and spacing of the conductive layers does not change, or changes only insignificantly.

In a preferred embodiment, the sensor can be configured in such a way that its absorption unit, or the entire unit, can be easily replaced. With replacement of the absorption unit, only the absorption layer may be replaced, or the “sensor head” containing the two conductive layers with the absorption layer lying between them may be replaced.

The sensor comprises at least one porous absorption layer. The absorption layer is liquid absorbent, particularly water and electrolyte absorbent. This means that said layer can absorb a certain amount of liquid from the environment. The advantage of this is that said absorption layer is able to collect and concentrate the liquid that is to be detected. This allows even small quantities of liquid in the housing to be detected by the sensor, and allows the sensor to transmit a reliable and precise signal. With a capacitive sensor, the absorption layer is preferably positioned between two conductive layers.

Advantageously, the absorption layer is a dielectric material. Said dielectric material forms an electrically non-conductive layer. The absorption layer is preferably arranged between two electrically conductive layers. The advantage of this configuration is that the liquid can be easily absorbed between two electrically conductive layers, thereby changing the capacitance. This capacitance change is dependent upon the type of liquid that is absorbed into the absorption layer.

Expediently, at least one electrically conductive layer has pores. The advantage of this is that the liquid to be detected can reach the absorption layer more easily by passing through the pores. The sensor can thereby detect the type of liquid more rapidly and reliably.

The absorption layer is, for example, a non-woven fabric, a woven fabric, a microporous membrane, a paper, a coated film, or the like, or a combination of such materials.

In one preferred embodiment, the absorption layer (3) comprises a non-woven fabric. The non-woven fabric preferably has fibers which contain an organic polymer. The polymer is preferably a synthetic polymer. Said synthetic polymer is preferably chosen from the group of polyesters, polyamides, polyacrylates, polymethacrylates, polyoxyalkylenes, polyacids, and copolymers thereof, natural polymers such as cellulose or modified natural polymers such as viscose, polyurethanes, silicones, and polyolefins and polymers which are hydrophilized by chemical or physical methods, particularly provided with charges on the surface. In one particular embodiment, ionic polymers are used.

Preferred are polymers and/or non-woven fabrics which experience only slight swelling when they come into contact with liquid.

One advantage of using non-woven fabrics as the absorption layer is their filter effect in relation to particulate contamination. Specifically, particles of dirt present in the battery could soil the sensor. If non-woven fabrics are used as the absorption layer, however, these particles are retained in the edge areas (filtered), so that the majority of the sensor is able to come into contact only with the liquid. In this case, it is conceivable to configure the porous absorption layer to have a larger surface area than the electrically conductive layers above and below it, so that the overlapping areas of the absorption layer can act as a filter element, thereby protecting the sensor from soiling.

Particularly suitable are non-woven fabrics made of polar fiber polymers and hydrophilic non-wovens. The advantage of a non-woven fabric is that liquids can be very rapidly absorbed and become uniformly distributed in the absorption layer. Due to their labyrinthine fiber structure, non-woven fabrics have a high absorption capacity for liquids. By correspondingly varying the non-woven fabrics, the sensor can be adapted very well to respective applications. Non-woven fabrics made of polyolefins, for example, have a very good wetting behavior in relation to oils and the like, however they do not absorb water due to their polar surface. Non-woven fabrics made of polar fiber polymers, such as polyester or polyamide, can often partially absorb water or other polar liquids in the polymer itself, and can hold these in large amounts in the spaces between its fibers. Polar non-woven fabrics are therefore particularly well suited for the absorption and detection of polar liquids, such as water and aqueous electrolytes or organic polar electrolytes with polar conducting salt additives. Additionally, particularly non-woven fabrics that are made hydrophilic through post-production processing enable a significant increase in wettability of the absorption layer, and thereby an even faster selective detection of liquid by the sensor.

In preferred embodiments, the non-woven fabric is a spunbonded non-woven fabric, a wet-laid non-woven fabric, a dry-laid non-woven fabric, a meltblown non-woven fabric, or an electrostatically spun non-woven fabric. The advantage of spunbonded non-woven fabrics is that the concentration of substances that might interfere with the selective detection of the liquid can be kept low. If the non-woven fabric still contains residues of wetting agents or other residues from production or post-production processing, these should be removed in advance. Particularly advantageous is the use of homogeneous spunbonded non-woven fabrics which have been produced via meltblowing.

Wet-laid non-woven fabrics are also highly homogeneous, for example, due to the possibility of using very fine fibers in the production process. In this case, the non-woven fabrics, as mentioned above, should be cleaned after production.

It is conceivable to treat the non-woven fabrics in a further step with a medium which interacts with the aqueous media or with the electrolyte, thereby intensifying and/or improving the respective signal.

The non-woven fabrics preferably have fine fibers, for example, with average diameters of less than 10 μm or less than 5 μm. With such non-woven fabrics, the capillary effect is high, which causes a rapid absorption of liquids. In addition, non-woven fabrics can be used, the fibers of which are split by a subsequent mechanical treatment, i.e., are separated into fiber fibrils.

Non-woven fabrics which contain very finely fibrillated so-called “pulp materials” can also be used. In these, both natural pulps (e.g., cellulose) and synthetic pulps (e.g., polyolefins; polyamides) can be used.

In one particular embodiment, the non-woven fabric is grafted, in particular, it is equipped with hydrophilic groups through secondary chemical processing. Such treatment also permits the use of non-woven fabrics made of a non-polar base material, for example, polyolefins, for absorbing polar substances. In this manner, a particularly high absorption rate for polar liquids can be achieved. This high absorption rate further leads to a full saturation of the absorption layer of the sensor with the liquid, and ultimately to an extremely fast and reliable, selective detection of the liquid located in the absorption layer by the sensor. For example, polyolefins can be equipped with ionic groups, preferably acrylic acid or maleic acid anhydride, through grafting.

Preferably, materials which are capable of absorbing more than 100% of their own weight in liquid are used. Super absorbers could also be used. The non-woven fabric preferably has a water rise level of at least 3, preferably of at least 10 mm/10 min, or at least 50 mm/10 min (5 mm strips of non-woven fabric after 20 min, measured according to the exemplary embodiment).

The sensor advantageously comprises means for connecting to a signal evaluation unit. The advantage of this is that the sensor can be connected to a signal evaluation unit in a simple and cost-effective manner, allowing its signals to be prepared for further processing.

The means for connection to a signal evaluation unit expediently comprise wired, wireless and/or optical means. The advantage of this is that wired means enable common and therefore cost-effective communication with a signal evaluation unit. If the wired means are embodied as a flat ribbon cable, the sensor can also be positioned in narrow or poorly accessible housings and can be connected to the signal evaluation unit. If wireless means are used, it is not necessary to conduct wiring out of the housing or to provide an opening, thereby substantially reducing the cost of assembling the sensor. If optical means, for example in the form of glass fibers, are used, the signals can be transmitted without adulteration by electromagnetic factors.

The conductive layers can be metallic films or sheets. Said layers can be partially perforated, which facilitates and accelerates the absorption of liquid into the intermediate layer. This arrangement has the advantage of easy handling and enables an easy replacement of the conductive layer.

The sensor is expediently embodied to be reusable. The advantage of this is that the sensor does not have to be replaced each time it detects liquid. This reduces the cost, particularly of maintaining the sensor. If it should nevertheless be necessary to replace the sensor, for example, due to mechanical damage, it is also advantageous to arrange the sensor in such a way that it can be replaced in the easiest possible manner.

It is also conceivable to use multiple sensors in the battery housing, said sensors being attached at different heights, for example. This allows a leak fill level to be detected. In this connection, a device in the form of a release valve or a pump would be conceivable, which would reliably conduct a leak in the form of condensation water or waste water to the outside. This device could then be controlled by the sensor. For example, if condensation water is detected by the sensor, said water could be removed from the battery housing via a controllable valve.

Also a part of the subject matter of the invention is an apparatus (6) for storing energy, comprising at least one apparatus for storing electrical energy, which apparatus is arranged inside a housing (7), and at least one sensor (1) according to the invention, which cooperates with the interior of the housing (7) to detect liquids inside the housing (7).

With an apparatus, it is advantageous for the sensor to be arranged in the lowermost region of the housing. In this context, “lowermost” refers to the lowest position during regular operation of the apparatus. The lowest position is therefore the position to which the liquids flow during operation, and where said liquids accumulate. The lowest position can also be that of a partial region of the housing. The advantage of this is that a liquid to be detected by the sensor naturally flows downward in the direction of the sensor. Otherwise, it would be necessary to conduct liquids correspondingly present in the housing to the sensor, if applicable, via pumps or the like, for the selective detection of said liquids. Eliminating a pump of this type further decreases the cost of an apparatus of this type. The movement of the liquid to the sensor can be supported by the configuration of the housing, for example, with grooves and inclined surfaces.

In a particular embodiment, the sensor is arranged outside of the housing of the apparatus. In this case, it is connected to a connection for exchanging liquids with the housing. This allows the sensor to be protected from aggressive liquids or elevated temperatures in the interior of the housing. It also ensures an extremely simple and cost-effective assembly of the sensor along with its replaceability. Finally, a shielded housing will not interfere with the possible wireless transmission of data measured by the sensor to a signal evaluation unit. The liquid to be detected can be transferred to the sensor by means of gravity, for example, or via capillaries, so that the liquid flows naturally to the sensor, or by means of a pump, which pumps the liquid to the sensor at regular intervals and/or when liquid to be detected is present. This has the advantage that the sensor can be arranged in any position, for example, even above the housing of the apparatus.

In one particular embodiment, multiple sensors are arranged at different positions in the housing. The advantage of this is that the arrangement of multiple sensors allows a redundant, selective detection of the liquid to be detected, even if one individual sensor fails. The site of a leak can also be better identified, for example, by different sensors transmitting different signals, which indicate a corresponding distribution of the liquid in the housing: If multiple sensors are arranged one above the other, spaced vertically, in other words, at different levels inside the housing, this allows a location or a quantity of a leak to be estimated.

In a further, particular embodiment, at least one sensor is arranged in a recess, which is preferably positioned at the bottom of the housing. The advantage of arranging at least one sensor in a recess is that the recess can be used to collect a liquid that is to be detected. Additionally, this makes the space that is customarily present in the housing available for the positioning of energy storage cells, making it unnecessary to modify the cells with respect to their space requirement.

In one particular embodiment of the invention, a part of the housing, particularly the bottom, comprises a conductive layer, which forms a conductive layer of the sensor. The advantage of this is that it allows the sensor to be completely integrated into the housing, thus requiring a minimum of space.

The apparatus expediently comprises means for regenerating the sensor, particularly means for heating and/or cooling. The advantage of this is that by applying means of this type, for example, a heating system, a fan, or the like, liquid that is located in the absorption layer can be re-evaporated, thereby returning the sensor to its original state prior to detection of the liquid. The sensor is therefore reusable. A further advantage of this is that the means for heating and/or cooling make it possible to control the temperature of the housing, particularly of the liquid and the sensor, so that the selective detection of the liquid can always be performed at the same temperature. The reliability of the selective detection of the liquid is thereby increased.

In one preferred embodiment, the system is embodied as “fail-safe.” In this embodiment, the system recognizes when the sensor is being operated with a short circuit, or when it is isolated from the measurement unit. Both cases are detected and evaluated by the signal processing unit. This serves to ensure that a failed sensor will be detected, therefore, no false signals will be transmitted and especially, no change in the battery will be detected. The monitoring system can also be embodied in such a way that electrical or optical properties are evaluated within a defined frequency spectrum. A further improvement in selectivity is thereby achieved.

In a preferred embodiment, the sensor is connected to a signal evaluation unit. The signal evaluation unit is preferably a part of the monitoring system according to the invention. In the evaluation unit, the signal from the sensor is received, preferably digitalized, and then processed and transmitted. The evaluation unit is preferably an electronic evaluation unit, which is also preferably controllable. It is able to compare the data transmitted by the sensor with stored data, for example, characteristic values, signal profiles, signal histories, or signal gradients. On the basis of said comparison, the evaluation unit then decides which medium is in contact with the sensor, and, if applicable, the properties of this medium (ion concentration, type of ions). On the basis of a higher-level control unit, for example, the evaluation unit generates adequate, further processed signals, for example, 0 to 10 V analog, 0/10 V digital, 4 to 20 mA analog, serial signals or USB.

In the preferred embodiments, the signal evaluation unit transmits the information to a battery management system (BMS). A system of this type is frequently already provided in conventional battery systems. In such cases, the signal evaluation unit can be directly integrated into the BMS. This has the advantage that all safety-relevant data are monitored and managed, and optionally stored, in one unit. The unit is able to make “decisions” based upon all of the information.

The unit can be embodied as autonomous, and can monitor the safety of the battery.

Also part of the subject matter of the invention is a monitoring system (1, 5, 6) for monitoring apparatuses for storing energy, comprising an apparatus (6) for storing energy according to the invention and a signal evaluation and control device (5), which cooperate in such a way that when the sensor (1) selectively determines whether it is in contact with water or with an electrolyte, or optionally is not in contact with any liquid, the signal evaluation and control device (5) isolates the apparatus (6) from a load of the apparatus (6) to prevent damage, and/or generates a signal that the apparatus (6) should be replaced.

Also part of the subject matter of the invention is a method for monitoring apparatuses (6) for storing energy, comprising the steps at least intermittent monitoring by the sensor (1) to determine whether water or an electrolyte or, if applicable, no liquid is present in the housing of the apparatus, generation of a detection signal by the sensor (1) on the basis of a result of said monitoring, reception and evaluation of the detection signal generated by the sensor (1) by means of a signal evaluation and control device (5), and control of the apparatus (6) so as to prevent damage to the apparatus (6) and/or for the continued operation of the apparatus (6) on the basis of the received and evaluated detection signal by means of the signal evaluation and control device (5).

The method advantageously comprises the step of at least intermittent monitoring to determine whether the sensor has short-circuited and/or has been isolated from the signal evaluation and control unit. The advantage of this is that it ensures that a sensor that has failed will be detected, therefore no leaks will occur which cannot be detected due to the failed sensor. This significantly increases the reliability of monitoring apparatuses for storing energy.

The at least intermittent monitoring comprises embodiments in which the sensor performs measurements at intervals, continuously, or under certain circumstances. The advantage of continuous measurement is that a defective or failed sensor will be detected immediately. However, if measurements are taken only at intervals, energy is conserved. Alternatively, it is possible for the sensor to be automatically or manually activated when certain events occur. In one possible embodiment within this context, a signal evaluation and measurement first evaluates a signal from the sensor when a significantly increased capacitance is measured at the sensor. Finally, it is possible for the sensor to perform measurements only or additionally when an energy storage/generator/management system that is connected to the sensor or to the apparatus reports an error. For example, if a management system of this type detects a temperature that is too high inside the housing of the apparatus, said system concludes that there is a leak in the cooling system, or a high internal resistance is measured by the management system, which may be caused by an energy storage or generator cell losing electrolyte. If the sensor then also selectively detects a possible liquid, a corresponding error can be identified faster and more accurately.

Also part of the subject matter of the invention is the use of a sensor (1) according to the invention to monitor apparatuses (6) for storing energy.

It is also conceivable for the sensor and/or the evaluation unit and/or the signal transmitting lines to be electrically shielded, so that potential interference signals from the power electronics of the battery will not negatively affect the measurement result. This is advantageous, for example, for automobile and safety-relevant applications, as such shielding reduces the susceptibility of the sensor to failure.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a sensor according to a first embodiment, connected to a signal evaluation unit;

FIGS. 2a and 2b are apparatuses for storing energy, according to a first embodiment, having a sensor;

FIGS. 3a and 3c are apparatuses according to a thirteenth embodiment, having a sensor;

FIG. 3b is an apparatus according to a twelfth embodiment, having a sensor;

FIG. 4 is a statistical capacitance curve for a sensor according to the embodiment, as a function of the time for different liquids; and

FIG. 5 is a capacitance curve for a sensor according to the invention, as a function of time, for the addition of water and the addition of electrolyte.

Corresponding reference numerals indicate corresponding parts throughout the several views of the drawings.

### DETAILED DESCRIPTION

Example embodiments will now be described more fully with reference to the accompanying drawings.

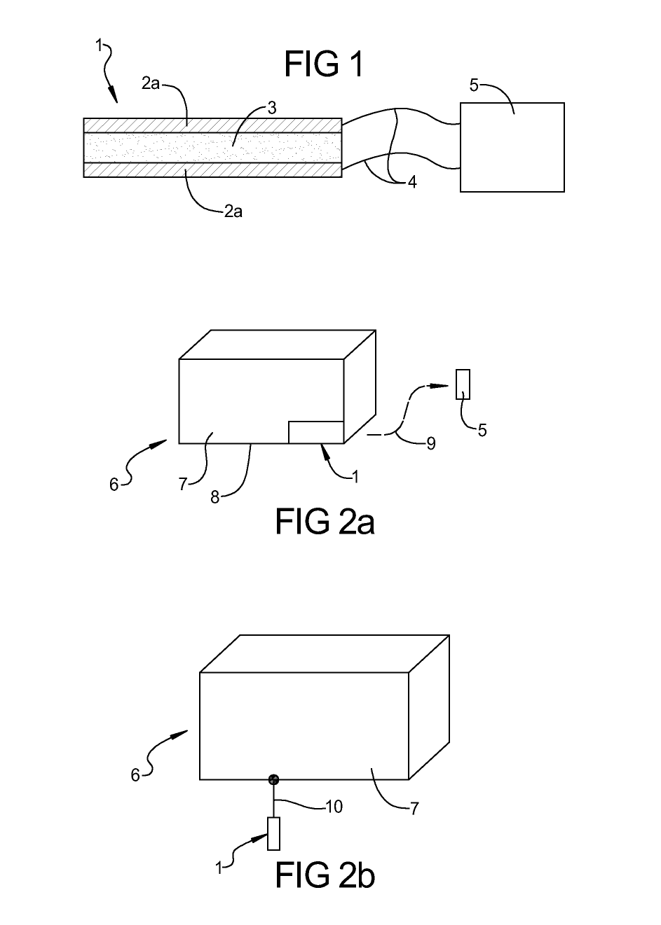

Particular exemplary embodiments of sensors and apparatuses according to the invention are shown in FIGS. 1 through 3. In FIG. 1, reference symbol 1 identifies a sensor for selectively detecting liquids in apparatuses for storing energy, which sensor is embodied for selectively detecting at least two of the liquids water, demineralized water, cooling medium and electrolyte. The sensor 1 further comprises two electrically conductive layers 2a, 2b between which an absorption layer 3 in the form of a dielectric is arranged. The electrically conductive layers 2a, 2b are connected to a signal evaluation unit 5 via cable 4. The electrically conductive layers 2a, 2b are arranged parallel with one another. The absorption layer 3 in the form of a dielectric is embodied as electrically non-conductive and as porous. When the absorption layer 3 absorbs liquids, the capacitance of the capacitor comprised of the electrically conductive layers 2a, 2b and the absorption layer 3 changes. Said change in capacitance is dependent upon the type of liquid and/or its dielectric constants. The horizontal arrangement of the sensor 1 or the capacitor shown in FIG. 1 is not intended to be restrictive, in other words, the sensor 1 can also be oriented horizontally, or in any other position.

FIG. 2 shows apparatuses for storing energy, comprising a sensor 1. FIG. 2a shows a perspective view of a housing 7 for a battery 6. In the lower region B of the housing 7, a sensor 1 is arranged horizontally and is connected to a signal evaluation unit 5 by wireless means 9.

In contrast to FIG. 2a, FIG. 2b shows the sensor 1 arranged not inside the housing 7 for the battery 6, but outside of the housing 7. In this case, the sensor 1 is connected to the housing 7 via a line 10, so that a liquid can then be conducted via the connection 10 to the sensor for the selective detection of said liquid. This can be accomplished by means of gravity, by arranging the sensor below the housing 7, so that the liquid flows to the sensor 1 by virtue of gravity, or can be accomplished actively, for example, by means of a pump, which conveys the liquid to be detected to the sensor 1.

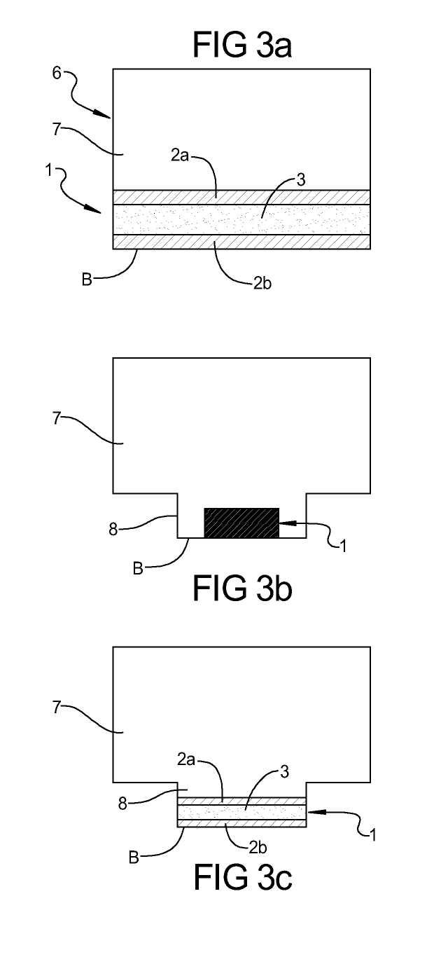

FIG. 3a shows a sensor 1, which is arranged in the housing 7 of a battery 6. Said sensor 1 comprises two electrically conductive layers 2a, 2b, between which an absorption layer 3 is arranged. In this case, the sensor 1 and/or the housing 7 are embodied in such a way that the lower, conductive layer 2b of the sensor 1 is formed by the housing 7, in other words, the lower conductive layer 2b of the sensor 1 forms a base B of the housing 7. In this case, the upper conductive layer 2a is arranged separately from the housing 7.

FIG. 3b shows a further possible embodiment of an apparatus for storing energy in the form of a battery 6 with a sensor 1. In the lower region, in other words, in the region of the base B of the housing 7, a recess 8 is arranged. Said recess 8 serves both to position the sensor 1 in the recess 8 and as a tray for collecting the liquids occurring in the housing 7. Finally, FIG. 3c shows essentially a combination of embodiments of the apparatuses according to FIGS. 3a and 3b. A base B of the recess 8 is embodied according to FIG. 3a, in other words, the lower, conductive layer 2b of the sensor 1 is formed by the base B of the recess or of the housing 7. The upper conductive layer 2a is then arranged separately from the recess 8 and/or the housing 7.

In summary, the invention has the advantage that liquids can be detected and differentiated in a simple and reliable manner in apparatuses for storing energy, thereby preventing damage to the energy storage apparatus caused by liquids.

### EMBODIMENTS

### Testing of Different Sensor Materials

Sensors having different absorption layers were produced and tested. The following materials were used as electrically conductive layers, with the surface areas used measuring between 0.5 and 4 cm²: copper films of various thicknesses; aluminum film; perforated copper film (approx. 10 holes/cm²; hole diameter approx. 0.2 mm); copper film and stainless steel film (steel 316/V4A) (with the stainless steel film behind the housing); nickel/gold film.

Between the electrically conductive layers and the absorption layer, an additional electrically insulating layer is applied. This layer is ideally securely connected to the electrically conductive layers (leakage fluid is unable to reach between electrically conductive layer and electrically insulating layer as a result of adhesion) and can be characterized by insulating varnish, coating film (PA, PI, PEN) or other thin-layer insulating materials. In this case, an electrically insulating varnish can be applied by spraying, brushing, etc., and a coating film can be applied by lamination.

In all experiments, it was found that the influence of the material used in the conductive layer was small. Only when the sputter-coated non-woven fabric was used was the signal resolution somewhat poorer. This can be explained by the inhomogeneous overall layer thickness, and by the relatively small layer thicknesses of metal about the fibers. Nevertheless, even in these experiments, a principal suitability was found.

The following non-woven materials were used as absorption layers:

### Example 1

Evolon 117, spunbonded non-woven fabric comprised of split fibers, which are made of PET and PA6, and which were mechanically split/fibrillated post production, obtainable from the Evolon company.

### Example 2

PBT meltblown spunbonded non-woven fabric PLURATEXX 5021; the Freudenberg company.

### Example 3

PP meltblown spunbonded non-woven fabric FS 2192-11 SG; the Freudenberg company; this fabric is chemically grafted with acrylic acid (UV-induced grafting reaction) post production. The advantage of this grafted non-woven fabric is its extremely high absorption rate for polar liquids. The high absorption rate leads to a rapid full saturation of the porous absorption layer, and therefore leads to a rapid, reliable “start-up” of the sensor.

### Example 4

PET wet-laid non-woven fabric FFA 2033; the Freudenberg company, washed with distilled water.

### Example 5

PET dry-laid non-woven fabric H 1015; the Freudenberg company, washed with distilled water.

### Example 6

Polyolefin wet-laid non-woven fabric FS 2200/055 the Freudenberg company, made of PE and PP fibers and fibrillated PE pulp, chemically grafted with acrylic acid post production.

For the non-woven fabrics according to examples 1 through 6, the respective water rise level was determined. For this purpose, a 5 mm wide strip of non-woven fabric was dipped in water and the rise level of the water (weighted mean of the rise level front) read after 10 minutes. The water rise level is a measurement of the wetting of the non-woven fabric, namely the absorption rate, and therefore of the “start-up” of the sensor. The results are summarized in Table 1.

TABLE 1
Properties of various non-woven fabrics

| | | | | | | Water |
|---|---|---|---|---|---|---|
| | Non- | | | Surface | Thick- | level |
| Ex- | woven | Pro- | | wt. | ness | (mm/10 |
| ample | fabric | duction | Polymer | (g/m²) | (mm) | min) |
| 1 | EVOLON | Spun- | PET & | 200 | 0.4 | 5-10 |
| | | bonded | PA6 | | | |
| | | & split | | | | |
| 2 | PLURATEXX | Melt- | PBT | 55 | 0.3 | 5 |
| | 5021 | blown | | | | |
| 3 | FS 2192- | Melt- | PP + | 38 | 0.11 | >80 |
| | 11SG | blown | acrylic | | | |
| | | | acid | | | |
| 4 | FFA 2037 | Wet-laid | PET | 155 | 0.5 | 5 |
| | | non- | | | | |
| | | woven | | | | |
| 5 | H 1015 | Dry-laid | PET | 150 | 0.27 | 5 |
| | | non- | | | | |
| | | woven | | | | |
| 6 | FS 2200/055 | Wet-laid | PE/PP + | 50 | 0.12 | >50 |
| | | non- | acrylic | | | |
| | | woven | acid | | | |
| | | with PE | | | | |
| | | pulp | | | | |

### Behavior of the Sensor in Relation to Water and Electrolytes

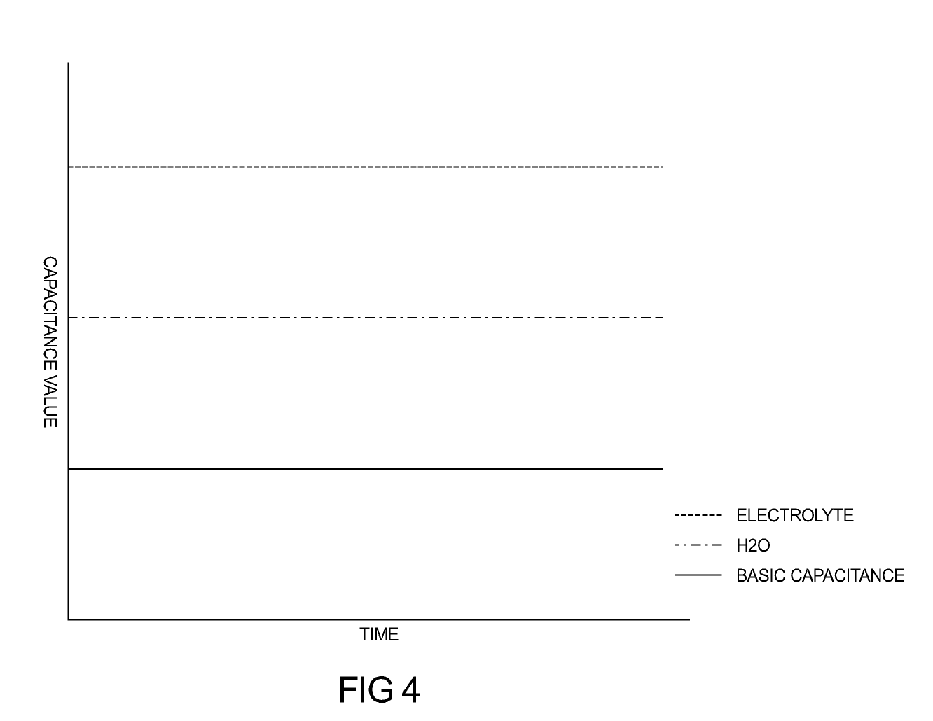

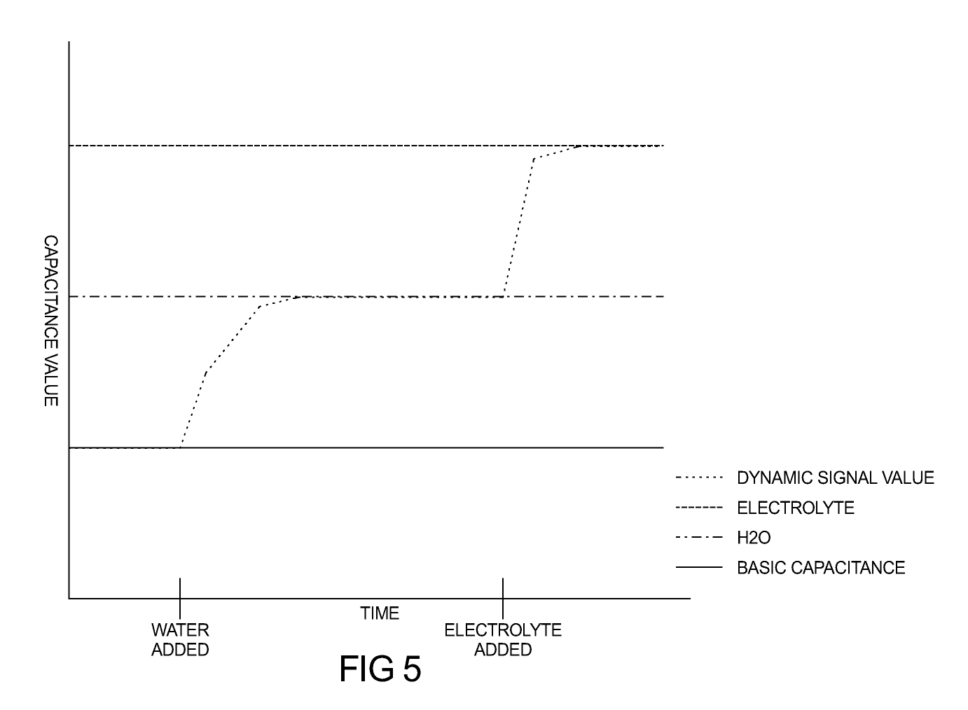

The following experiments were conducted using Cu films as electrically conductive layers and EVOLON 117 as the absorption layer. FIGS. 4 and 5 show the expected selectivity with respect to the leakage media, as a function of time. The capacitance value shown here on the y axis is proportional to the measurement capacitance of the sensor. Whereas the basic capacitance of the unwetted sensor element lies at a low level (approx. 80 relative units), an aqueous solution, namely tap water, demineralized water or a water/glycol mixture (BASF GL48), causes a sudden increase in capacitance by a factor of 40 to about 3250 relative units. Electrolytic solutions, in turn, have an even higher dielectric constant and lead to an about 1000 times higher relative capacitance as compared with the base value, and to a 20 times higher relative capacitance as compared with aqueous solutions. The presence of electrolytes can be detected even if the porous absorption layer was already fully saturated with water before coming into contact with the electrolyte (see FIG. 5). Even small quantities (<1 vol. %) of electrolyte then lead to a substantial increase in capacitance.

FIGS. 4 and 5 show that the sensor system is capable of sensitively and selectively differentiating between the occurring leakage media. Moreover, its sensitivity is especially high, particularly with the detection of electrolyte, which is particularly critical in practical terms, and with the differentiation of said electrolyte from the other media. In addition, FIG. 5 shows that a sensor that is already charged with water, with its absorption layer being already fully charged with water, is able to rapidly and accurately detect electrolyte, even when only small quantities of said electrolyte are added. FIG. 4 shows that the various aqueous media have different capacitances, and can therefore be essentially differentiated from one another.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A sensor (1) for selectively detecting liquids in apparatuses for storing energy, wherein the sensor (1) comprises at least one porous absorption layer (3) for absorbing liquids.

2. The sensor according to claim 1, wherein the sensor (1) detects selectively whether it is in contact with water or with an electrolyte or is not in contact with any liquid.

3. The sensor (1) according to claim 1, wherein the sensor (1) is designed as a capacitive and/or optical sensor.

4. The sensor (1) according to claim 1, wherein the absorption layer (3) is designed as a dielectric and is arranged between two electrically conducting layers (2a, 2b).

5. The sensor (1) according to claim 4, wherein at least one electrically conducting layer (2a, 2b) has pores.

6. The sensor (1) according to claim 1, wherein the absorption layer (3) comprises a non-woven.

7. The sensor (1) according to claim 6, wherein the non-woven has fibers containing a polymer selected from the group of the polyesters, polyamides, polyacrylates, polymethacrylates, polyoxyalkylenes, polyacids and copolymers thereof, natural polymers such as cellulose or modified natural polymers such as viscose, polyurethanes, polysilicones, and polyolefins and polymers which are hydrophilized by chemical or physical methods.

8. The sensor (1) according to claim 6, wherein the non-woven is a spunbonded web, in particular a wet-laid web, dry-laid web, meltblown web or an electrostatically spun web.

9. An apparatus (6) for storing energy, comprising at least one store for electric energy, which is arranged in the inside of a housing (7), and at least one sensor (1) according to at least one of the preceding claims, wherein the sensor (1) cooperates with the inside of the housing (7) for detecting liquids in the housing (7).

10. The apparatus (6) according to claim 9, wherein the sensor (1) is arranged in the lowermost region (B) of the housing (7).

11. The apparatus (6) according to claim 9, wherein a plurality of sensors (1) are arranged at various positions in the housing (7) and/or at least one sensor (1) is arranged in at least one recess (8).

12. The apparatus (6) according to claim 9, wherein a part (B) of the housing, in particular the bottom, comprises a conductive layer (2a, 2b), which forms a conductive layer (2a, 2b) of the sensor (1).

13. The apparatus (6) according to claim 9, wherein the apparatus (6) comprises means for regenerating the sensor, in particular means for heating and/or cooling.

14. The apparatus (6) according to claim 9, in the form of a battery, a fuel cell, an accumulator or capacitor.

15. A monitoring system (1, 5, 6) for monitoring apparatuses for storing energy, comprising:
an apparatus (6) for storing energy; and
a signal evaluation and control device (5), which interact such that,
when a sensor (1) detects selectively whether it is in contact with water or with an electrolyte,
the signal evaluation and control device (5) isolates the apparatus (6) from a load of the apparatus (6) in order to avoid damage and/or produces a signal for changing the apparatus (6).

16. A method for monitoring apparatuses (6) for storing energy, comprising the steps
at least intermittent monitoring, using a sensor (1) for determining whether there is water or an electrolyte in the housing of the apparatus,
producing a detection signal by way of the sensor (1) as a function of a result of the monitoring,
receiving and evaluating the detection signal produced by the sensor (1) using a signal evaluation and control device (5) and
controlling the apparatus (6) for avoiding damage to the apparatus (6) and/or for the further operation of the apparatus (6) on the basis of the received and evaluated detection signal using the signal evaluation and control device (5).

17. The method according to claim 16, comprising the step of at least intermittently monitoring whether the sensor (1) is short-circuited and/or is isolated from the signal evaluation and control device (5).
